(19) United States
(12) Patent Application Publication
(10) Pub. No.: US 2018/0138053 A1
(43) Pub. Date: May 17, 2018

(54) Wet Etching Method and Etching Solution

(71) Applicant: Central Glass Company, Limited, Ube-shi, Yamaguchi (JP)

(72) Inventors: Akifumi YAO, Ube-shi, Yamaguchi (JP); Kunihiro YAMAUCHI, Ube-shi, Yamaguchi (JP); Masaki FUJIWARA, Chiyoda-ku, Tokyo (JP); Tatsuo MIYAZAKI, Chiyoda-ku, Tokyo (JP)

(21) Appl. No.: 15/573,302

(22) PCT Filed: Jun. 22, 2016
(86) PCT No.: PCT/JP2016/068456

§ 371 Date: Nov. 10, 2017

(30) Foreign Application Priority Data
Jul. 23, 2015 (JP) 2015-145487

(51) Int. Cl. H01L 21/3213; C23F 1/14; H01L 21/311; H01L 21/306

(52) U.S. Cl. CPC H01L 21/32134; C23F 1/14; H01L 43/12; H01L 21/30612; H01L 21/31111

(57) ABSTRACT

Disclosed is a wet etching method for etching a metal-containing film on a substrate with the use of an etching solution, wherein the etching solution contains an organic solvent and a β-diketone having a trifluoromethyl group and a carbonyl group bonded to each other, and wherein the metal-containing film contains a metal element capable of forming a complex with the β-diketone.

### FIELD OF THE INVENTION

The present invention relates to a wet etching method and etching solution for a metal-containing film used in a semiconductor manufacturing process or the like.

### BACKGROUND ART

In a manufacturing process of semiconductor devices, etching treatment is performed to form desired patterns on metal-containing metals such as metal films for use as metal gate materials, electrode materials or magnetic materials etc., and metal compound films for use as piezoelectric materials, LED luminescent materials, transparent electrode materials or dielectric materials etc.

As a method for etching a metal-containing film, a dry etching method using a β-diketone is known. For example, there is disclosed a method for forming a patterned metal film, including a dry etching step of anisotropically oxidizing a seed layer of transition metal and etching the oxidized seed layer with the use of a gas of HFAc or the like (see Patent Document 1). There is also disclosed a method for dry etching a film of metal such as Co, Fe, Zn, Mn or Ni on a substrate with the use of an etching gas containing a β-diketone and H₂O (see Patent Document 2).

In addition to the dry etching method using the etching gas as disclosed in Patent Documents 1 and 2, a wet etching method using an etchant is known. In a manufacturing process of semiconductor devices, wet etching treatment is performed with the use of an etching solution containing an inorganic acid or organic acid and an oxidizing substance (see Patent Documents 3, 4 and 5).

There is further disclosed a method for selectively etching Ti with the use of an etching solution containing an organic amine compound, a basic compound and an oxidizing agent in an aqueous medium and having a pH of 7 to 14 (see Patent Document 6).

### PRIOR ART DOCUMENTS

### Patent Documents

Patent Document 1: Japanese Laid-Open Patent Publication No. 2012-114287

Patent Document 2: Japanese Laid-Open Patent Publication No. 2014-236096

Patent Document 3: Japanese Laid-Open Patent Publication No. 2013-149852

Patent Document 4: Japanese Laid-Open Patent Publication (Translation of International Publication) No. 2008-541447

Patent Document 5: Japanese Laid-Open Patent Publication (Translation of International Publication) No. 2008-512869

Patent Document 6: Japanese Laid-Open Patent Publication No. 2013-33942

### SUMMARY OF THE INVENTION

### Problems to be Solved by the Invention

As compared to dry etching, wet etching is advantageous in that costs of equipment and etchant are low; and a large number of substrates can be processed at a time. However, the conventional etching solutions could react with not only the metal-containing films as the etching targets but also the nontarget substrates. This leads to deterioration in the performance of devices to which such metal-contain films are mounted.

The present invention has been made in view of the above problem. It is an object of the present invention to provide a method for efficiently etching a metal-containing film on a substrate with the use of an etching solution.

### Means for Solving the Problems

The present inventors have found that, with the use of an organic solvent solution of a β-diketone in which a trifluoromethyl group and a carbonyl group are bonded to each other as an etching solution, it is possible to etch a metal-containing film on a substrate by formation of a complex between the β-diketone and a metal element of the metal-containing film. The present invention is based on this finding.

Namely, there is provided according to a first aspect of the present invention a wet etching method comprising: etching a metal-containing film on a substrate with the use of an etching solution, wherein the etching solution contains a β-diketone having a trifluoromethyl group and a carbonyl group bonded to each other and an organic solvent, and wherein the metal-containing film contains a metal element capable of forming a complex with the β-diketone.

There is provided according to a second aspect of the present invention an etching solution comprising: at least one kind of organic solvent selected from the group consisting of isopropyl alcohol, methanol, ethanol, propylene glycol monomethyl ether acetate (PGMEA), methyl ethyl ketone (MEK) and acetone; and a β-diketone having a trifluoromethyl group and a carbonyl group bonded to each other.

It is possible in the present invention to efficiently etch the metal-containing layer on the substrate with the use of the etching solution.

### DETAILED DESCRIPTION OF EMBODIMENTS

[Wet Etching Method for Metal-Containing Film]

In a wet etching method of the present invention, a metal-containing film on a substrate is etched with the use of an etching solution containing a β-ketone in which a trifluoromethyl group and a carbonyl group are bonded to each other.

The metal-containing film to be etched by the wet etching method of the present invention contains a metal element capable of forming a complex with the β-ketone. Examples of the metal element contained in the metal-containing film are Ti, Zr, Hf, V, Nb, Ta, Cr, Mo, W, Mn, Re, Fe, Ru, Os, Co, Rh, Ir, Ni, Pd, Pt, Cu, Ag, Au, Zn, Cd, Al, Ga, In, Sn, Pb and As. Each of these metal elements is capable of forming a complex with the β-ketone in the etching solution. The complex is formed between the metal element and the β-ketone in the etching solution and dissolved in the etching solution. As the metal element contained in the metal-containing film, Ti, Zr, Hf, V, Cr, Mn, Fe, Ru, Os, Co, Rh, Ir, Ni, Pd, Pt, Cu, Zn, Al, Ga, In, Sn, Pb and As are preferred. Particularly preferred are Ti, Zr, Hf, Cr, Fe, Ru, Co, Ni, Pt, Cu, Zn, Al, Ga, In, Sn and Pb.

Preferably, the metal-containing film is either a film made of a simple substance of the metal element, a film made of an alloy containing the metal element or a film made of a compound containing the metal element in the present invention. It is feasible to etch a laminate of these metal-containing films. As the alloy of which the metal-containing film is made, there can be used: an alloy of a plurality of the above metal elements, such as NiCo, CoFe, CoPt, MnZn, NiZn, CuZn or FeNi; or an alloy containing the other element as a dopant, such as CoFeB. As the compound of which the metal-containing film is made, there can be used: an intermetallic compound containing a plurality of the above metal elements; an oxide of the above metal element, such as hafnium oxide, ruthenium oxide, titanium oxide, indium tin oxide (ITO), indium zinc oxide (IZO), gallium oxide or lead zirconium titanium oxide; a nitride of the above metal element, such as GaN or AlGaN; a silicide of the above metal element, such as NiSi, CoSi or HfSi; an arsenide of the above metal element, such as InAs, GaAs or InGaAs; and a phosphide of the above metal element, such as InP or GaP. When the metal-containing film contains a plurality of elements, the composition ratio of the respective elements can be set to an arbitrary value.

There is no particular limitation on the substrate in the present invention as long as the substrate is made of a material that does not react with the etching solution during wet etching. As the substrate, for example, there can be used: a substrate of silicon semiconductor material such as silicon oxide, polysilicon, silicon nitride, silicon oxynitride or silicon carbide; or a substrate of silicate glass material such as soda-lime glass, borosilicate glass or silica glass. In addition to the metal-containing film, a film of silicon semiconductor material may be formed on the substrate.

In the present invention, the etching solution is a solution having, dissolved in an organic solvent, the β-diketone in which the trifluoromethyl group and the carbonyl group are bonded to each other. As compared to a β-diketone in which a trifluoromethyl group and a carbonyl group are not bonded to each other, the β-diketone in which the trifluoromethyl group (CF₃) and the carbonyl group (C═O) are bonded to each other allows high-speed etching and has less tendency to, when it forms a complex with the metal element, cause aggregation and deposition of the complex as a solid. Thus, the β-diketone in which the trifluoromethyl group and the carbonyl group are bonded to each other achieves a practical etching rate even without the addition of an acid etc. to the etching solution. There is no particular limitation on the β-diketone contained in the etching solution as longs as the β-diketone has a moiety at which the trifluoromethyl group (CF₃) and the carbonyl group (C═O) are bonded to each other (that is, a trifluoroacetyl moiety). Preferably, the β-diketone is one kind, or a combination of two or more kinds, selected from the group consisting of hexafluoroacetylacetone (also called 1,1,1,5,5,5-hexafluoro-2,4-pentanedione), trifluoroacetylacetone (also called 1,1,1-trifluoro-2,4-pentanedione), 1,1,1,6,6,6-hexafluoro-2,4-hexanedione, 4,4,4-trifluoro-1-(2-thienyl)-1,3-butanedione, 4,4,4-trifluoro-1-phenyl-1,3-butanedione, 1,1,1,5,5,5-hexafluoro-3-methyl-2,4-pentanedione, 1,1,1,3,5,5,5-heptafluoro-2,4-pentanedione and 1,1,1-trifluoro-5,5-dimethyl-2,4-hexanedione

There is no particular limitation on the organic solvent used in the etching solution. As the organic solvent, there can be used a primary alcohol, a secondary alcohol, a tertiary alcohol, a benzyl alcohol, an ether, an ester, a ketone, an amine, an amide, a glycol, a glycol ether, a halogenated alkane or a combination thereof. Specific examples of the organic solvent are isopropyl alcohol, methanol, ethanol, propylene glycol monomethyl ether acetate (PGMEA), methyl ethyl ketone (MEK), acetone and a combination thereof. These organic solvents are preferred because each of these organic solvents is widely available at low cost and has high compatibility with the β-diketone.

When the β-diketone is converted to a hydrate, the hydrate is deposited as a solid. A solution of the β-diketone in a water solvent thus causes a plurality of solid deposits and cannot be used as an etching solution. For this reason, the amount of water contained in the etching solution is preferably 1 mass % or less. Since a hydrate of the β-diketone is deposited as a solid, the presence of a large amount of water in the etching solution results in deposition of solid component as particles. The etching solution containing such particles is unfavorable in that the particles remain on the processing object and could become a cause of device problem.

The concentration of the β-diketone in the etching solution is preferably 1 to 80 mass %, more preferably 5 to 50 mass %, still more preferably 10 to 20 mass %. When the concentration of the β-diketone is too high, the etching solution becomes too expensive due to the fact that the β-diketone is generally higher in cost than the organic solvent. When the concentration of the β-diketone is too low, the etching may not proceed sufficiently.

The etching solution may consist essentially of the organic solvent and the β-diketone. Alternatively, the etching solution may contain a peroxide as an additive for increase in etching rate and improvement in etching selectivity. The peroxide additive is preferably selected from the group consisting of hydrogen peroxide, peracetic acid, potassium percarbonate, ammonium persulfate, sodium persulfate, potassium persulfate and potassium peroxysulfate. These peroxide compounds are preferred as the additive in the etching solution because each of these peroxide compounds is commonly available and is capable of implementing oxidation of the metal element of the metal-containing film and promoting complexation between the metal element and the β-diketone.

Further, various acids can be used as an additive in the etching solution for increase in etching rate and improve in etching selectivity as long as the processing object is not adversely affected by the acid. The acid additive is preferably selected from the group consisting of citric acid, formic acid, acetic acid and trifluoroacetic acid.

The amount of the additive is preferably 0.01 to 20 mass %, more preferably 0.5 to 15 mass %, still more preferably 1 to 10 mass %, based on the amount of the etching solution. As mentioned above, the etching solution may alternatively be formed from only the organic solvent and the β-diketone.

In the present invention, the metal-containing film is etched by immersing the processing object with the metal-containing film in the etching solution, or feeding the etching solution into etching equipment in which the processing object with the metal-containing film is placed, forming the metal complex by contact reaction of the etching solution with the metal-containing film of the processing object and thereby dissolving the metal-containing film in the etching solution.

The etching solution of the present invention enables etching of a material containing a metal element that forms a complex with the β-diketone, but does not enable etching of a silicon semiconductor material or silicate glass material that does not form a complex with the β-diketone. It is therefore possible to etch only the metal-containing film selectively against the substrate by the wet etching method of the present invention. In the case where two or more kinds of metal-containing films are formed on the substrate, it is feasible to etch one of the metal-containing films selectively against the other metal-containing films by virtue of a difference in etching rate between the metals contained in the metal-containing films.

There is no particular limitation on the temperature of the etching solution in the wet etching method of the present invention as long as the etching solution is maintained in a liquid state. The temperature of the etching solution can be appropriately set to about −10 to 100° C. For example, the boiling points of hexafluoroacetylacetone and 1,1,1,3,5,5,5-heptafluoro-2,4-pentanedione are about 70° C.; and the boiling point of trifluoroacetylacetone is about 105 to 107° C. Strictly measured values of the melting points of hexafluoroacetylacetone and trifluoroacetylacetone are not known. In view of the facts that: the boiling point and melting point of an organic compound are generally lowered by fluorination; and acetylacetone has a boiling point of 140° C. and a melting point of −23° C., it is assumed that the melting points of fluorinated acetylacetone, i.e., hexafluoroacetylacetone and trifluoroacetylacetone are lower than the melting point of acetylacetone.

There is also no particular limitation on the etching time in the wet etching method of the present invention. In view of the efficiency of the semiconductor manufacturing process, the etching time is preferably 60 minutes or less. Herein, the etching time refers to a period of time during which the processing object is in contact with the etching solution and can be, for example, a time of immersion of the substrate as the processing object in the etching solution or a time from introduction of the etching solution into a processing chamber in which the substrate as the processing object is placed for etching treatment until discharge of the etching solution from the processing chamber for completion of the etching treatment.

By the wet etching method of the present invention, it is possible to etch the metal-containing film as the etching target without etching the nontarget part such as substrate or silicon semiconductor material film.

The wet etching method of the present invention enables etching of the metal-containing film by means of low-cost wet etching equipment as compared to dry etching equipment, and thus leads to low-cost manufacturing of semiconductor devices.

(Device)

Metal-containing films of devices, which are manufactured in conventional semiconductor manufacturing processes, can be etched by the wet etching method of the present invention. It is possible to manufacture the devices at low cost with the use of the metal-containing films etched by the wet etching method of the present invention. Examples of such a device are a solar cell, a dynamic random access memory, a phase change memory, a ferroelectric memory, a magnetoresistive memory, a resistive memory and a MEMS.

### EXAMPLES

The present invention will be described in more detail below by way of the following examples. It should however be noted that the following examples are illustrative and are not intended to limit the present invention thereto.

Test samples used were respectively prepared by forming various films of 1 mm thickness on silicon substrates of 2 cm×2 cm size. The respective films were formed from metal simple substances, metal alloys and metal compounds by chemical vapor deposition (CVD).

Herein, the term “p-Si” is an abbreviation for polysilicon and refers to polycrystalline silicon. The term “SiN” refers to silicon nitride as represented by the chemical formula: SiNₓ. The term “SiON” refers to silicon oxynitride as represented by the chemical formula: SiOₓN_{y}. The term “ITO” refers to indium tin oxide, that is, a composite oxide in which indium oxide is doped with a small amount of tin oxide. The term “IZO” refers to indium zinc oxide, that is, a composite oxide in which indium oxide is doped with a small amount of zinc oxide. The term “PZT” refers to lead zirconium titanium oxide as represented by the chemical formula: Pb(ZrₓTi₁₋ₓ)O₃. Each of CoFe, GaN, NiSi, CoSi and HfSi does not mean that the composition ratio of the constituent elements is 1:1 and could be provided with an arbitrary composition ratio.

For wet etching test, etching solutions of various compositions were prepared using hexafluoroacetylacetone (HFAc), trifluoroacetylacetone (TFAc), 1,1,1,3,5,5,5-heptafluoro-2,4-pentanedione (HFPD) or acetylacetone (AcAc) as a β-diketone, and isopropyl alcohol (IPA), acetone, methanol as an organic solvent, and optionally adding hydrogen peroxide (H₂O₂) as an additive or a small amount of water. In Example 4-1, for example, an aqueous solution of 35 mass % of the hydrogen peroxide was added such that the amount of the hydrogen peroxide was 1 mass % relative to the total amount of the etching solution.

Further, a film of SiN, a film of SiOₓ and a film of Co were etched with the use of 1 mass % dilute nitric acid in Comparative Examples.

The etching rate of each sample was determined based on the thickness of the film before and after the wet etching treatment and the time of the wet etching treatment.

The test results are shown in TABLES 1 to 3.

TABLE 1

| | β-Diketone | | Solvent | | Additive | | | Etching |
|---|---|---|---|---|---|---|---|---|
| | | Content | | Content | | Content | Etching | rate |
| | Kind | [mass %] | Kind | [mass %] | Kind | [mass %] | target | [nm/min] |
| Example 1-1 | HFAc | 20 | IPA | 80 | — | — | Co | 3.3 |
| Example 1-2 | | | | | | | Fe | 5.2 |
| Example 1-3 | | | | | | | Ti | 2.1 |
| Example 1-4 | | | | | | | Zr | 1.2 |
| Example 1-5 | | | | | | | Hf | 3.1 |
| Example 1-6 | | | | | | | Cr | 2.6 |
| Example 1-7 | | | | | | | Al | 0.6 |
| Example 1-8 | | | | | | | Ru | 1.8 |
| Example 1-9 | | | | | | | Ni | 6.2 |
| Example 1-10 | | | | | | | Pt | 0.8 |
| Example 1-11 | | | | | | | Cu | 7.2 |
| Example 1-12 | | | | | | | CoFe | 2.3 |
| Example 1-13 | | | | | | | ITO | 3.3 |
| Example 1-14 | | | | | | | IZO | 3.5 |
| Example 1-15 | | | | | | | HfOₓ | 1.2 |
| Example 1-16 | | | | | | | RuOₓ | 1.8 |
| Example 1-17 | | | | | | | TiOₓ | 1.6 |
| Example 1-18 | | | | | | | GaOₓ | 1.4 |
| Example 1-19 | | | | | | | PZT | 2.4 |
| Example 1-20 | | | | | | | GaN | 3.3 |
| Example 1-21 | | | | | | | NiSi | 2.4 |
| Example 1-22 | | | | | | | CoSi | 1.5 |
| Example 1-23 | | | | | | | HfSi | 3.3 |
| Comparative | | | | | | | SiN | <0.1 |
| Example 1-1 | | | | | | | | |
| Comparative | | | | | | | SiOₓ | <0.1 |
| Example 1-2 | | | | | | | | |
| Comparative | | | | | | | p-Si | <0.1 |
| Example 1-3 | | | | | | | | |
| Comparative | | | | | | | SiC | <0.1 |
| Example 1-4 | | | | | | | | |
| Comparative | | | | | | | SiON | <0.1 |
| Example 1-5 | | | | | | | | |

TABLE 2

| | β-Diketone | | Solvent | | Additive | | | Etching |
|---|---|---|---|---|---|---|---|---|
| | | Content | | Content | | Content | Etching | rate |
| | Kind | [mass %] | Kind | [mass %] | Kind | [mass %] | target | [nm/min] |
| Example 2-1 | TFAc | 20 | IPA | 80 | — | — | Co | 2.5 |
| Example 2-2 | | | | | | | Fe | 4.6 |
| Comparative | | | | | | | SiN | <0.1 |
| Example 2-1 | | | | | | | | |
| Comparative | | | | | | | SiOₓ | <0.1 |
| Example 2-2 | | | | | | | | |
| Example 3-1 | HFPD | 20 | IPA | 80 | — | — | Co | 2.8 |
| Example 3-2 | | | | | | | Fe | 4.8 |
| Comparative | | | | | | | SiN | <0.1 |
| Example 3-1 | | | | | | | | |
| Comparative | | | | | | | SiOₓ | <0.1 |
| Example 3-2 | | | | | | | | |
| Example 4-1 | HFAc | 20 | acetone | 80 | — | — | Co | 3.1 |
| Example 4-2 | | | | | | | Fe | 5 |
| Comparative | | | | | | | SiN | <0.1 |
| Example 4-1 | | | | | | | | |
| Comparative | | | | | | | SiOₓ | <0.1 |
| Example 4-2 | | | | | | | | |
| Example 5-1 | HFAc | 20 | methanol | 80 | — | — | Co | 2.8 |
| Example 5-2 | | | | | | | Fe | 4.9 |
| Comparative | | | | | | | SiN | <0.1 |
| Example 5-1 | | | | | | | | |
| Comparative | | | | | | | SiOₓ | <0.1 |
| Example 5-2 | | | | | | | | |
| Example 6-1 | HFAc | 20 | IPA | 79 | H₂O₂ | 1 | Co | 15 |
| Example 6-2 | | | | | | | Fe | 32 |
| Comparative | | | | | | | SiN | <0.1 |
| Example 6-1 | | | | | | | | |
| Comparative | | | | | | | SiOₓ | <0.1 |
| Example 6-2 | | | | | | | | |
| Example 7-1 | HFAc | 5 | IPA | 95 | — | — | Co | 2.6 |
| Comparative | | | | | | | SiOₓ | <0.1 |
| Example 7-1 | | | | | | | | |
| Example 8-1 | HFAc | 50 | IPA | 50 | — | — | Co | 11.2 |
| Comparative | | | | | | | SiOₓ | <0.1 |
| Example 8-1 | | | | | | | | |
| Example 9-1 | HFAc | 20 | IPA | 79 | H₂O | 1 | Co | 6.2 |
| Comparative | | | | | | | SiOₓ | <0.1 |
| Example 9-1 | | | | | | | | |
| Example 10-1 * | HFAc | 20 | IPA | 75 | H₂O | 5 | Co | 8.2 |
| Comparative | | | | | | | SiOₓ | <0.1 |
| Example 10-1 * | | | | | | | | |
| Comparative | AcAc | 20 | IPA | 80 | — | — | Co | <0.1 |
| Example 11-1 | | | | | | | | |
| Comparative | | | | | | | SiOₓ | <0.1 |
| Example 11-2 | | | | | | | | |

* In Comparative Examples 10-1 and 10-2, there occurred particles in the etching solution.

TABLE 3

| | Acid | | Solvent | | Additive | | | Etching |
|---|---|---|---|---|---|---|---|---|
| | | Content | | Content | | Content | Etching | rate |
| | Kind | [mass %] | Kind | [mass %] | Kind | [mass %] | target | [nm/min] |
| Comparative | HNO₃ | 1 | water | 99 | — | — | SiN | 41.9 |
| Example 12-1 | | | | | | | | |
| Comparative | | | | | | | SiOₓ | 86 |
| Example 12-2 | | | | | | | | |
| Comparative | | | | | | | Co | 254.3 |
| Example 12-3 | | | | | | | | |

As is seen from Examples 1-1 and 1-2 and Comparative Examples 1-1 and 1-2, it was possible by the etching solution of the present invention to etch Co with a selectivity of 33 or higher against SiN or SiOₓ and to etch Fe with a selectivity of 52 or higher against SiN or SiOₓ. Further, it is seen from Examples 1-1 to 1-23 and Comparative Examples 1-1 to 1-5 that the metal-containing film containing a predetermined metal element was etched selectively against the silicon-based material by the etching solution of the present invention.

Even when TFAc was as the β-diketone, it was possible to etch Co with a selectivity of 25 or higher against SiN or SiOₓ and to etch Fe with a selectivity of 46 or higher against SiN or SiOₓ as is seen from Examples 2-1 and 2-2 and Comparative Examples 2-1 and 2-2. It is thus apparent that the metal-containing film was etched selectively against the silicon-based material.

Even when HFPD was as the β-diketone, it was possible to etch Co with a selectivity of 28 or higher against SiN or SiOₓ and to etch Fe with a selectivity of 48 or higher against SiN or SiOₓ as is seen from Examples 3-1 and 3-2 and Comparative Examples 3-1 and 3-2. It is thus apparent that the metal-containing film was etched selectively against the silicon-based material.

As is seen from Examples 4-1 and 4-2 and Comparative Examples 4-1 and 4-2, the metal-containing film was also etched selectively against the silicon-based material even when acetone was used as the organic solvent.

As is seen from Examples 5-1 and 5-2 and Comparative Examples 5-1 and 5-2, the metal-containing film was also etched selectively against the silicon-based material even when methanol was used as the organic solvent.

As is seen from Examples 6-1 and 6-2 and Comparative Examples 6-1 and 6-2, it was possible to increase the etching rate of Co, Fe and improve the selectivity of the metal-containing film against the silicon-based material by the addition of hydrogen peroxide as the additive.

It is seen from Examples 7-1 and 8-1 and Comparative Examples 7-1 and 8-1 that the metal-containing film was etched selectively against the silicon-based material even when the amount of HFAc contained was 5 mass % or 50 mass %.

As is seen from Example 9-1 and Comparative Example 9-1, the metal-containing film was etched selectively against the silicon-based material when the etching solution had a water content of 1 mass %. When the etching solution had a water content of 5 mass % as in Example 10-1 and Comparative Example 10-1, particles occurred in the etching solution and remained on the etching target. Such an etching solution from which particles remains on the etching target is unusable for etching of metal-containing films for semiconductor device applications.

When acetylacetone was used as the β-diketone, on the other hand, both of the etching rate of Co and the etching rate of SiO₂ were low so that the etching solution was difficult to use as is seen from Comparative Examples 11-1 and 11-2.

As is seen from Comparative Examples 12-1 to 12-3, the silicon-based material was etched because of the reaction of dilute nitric acid with SiN and SiOₓ. The etching selectivity of Co against the SiN was about 6. The etching selectivity of Co against SiOₓ was about 3. It was not possible to obtain a favorable etching selectivity.

1. A wet etching method comprising: etching a metal-containing film on a substrate with the use of an etching solution,
wherein the etching solution contains a β-diketone having a trifluoromethyl group and a carbonyl group bonded to each other and an organic solvent, and
wherein the metal-containing film contains a metal element capable of forming a complex with the β-diketone.

2. The wet etching method according to claim 1,
wherein the metal element is at least one kind of metal element selected from the group consisting of Ti, Zr, Hf, V, Nb, Ta, Cr, Mo, W, Mn, Re, Fe, Ru, Os, Co, Rh, Ir, Ni, Pd, Pt, Cu, Ag, Au, Zn, Cd, Al, Ga, In, Sn, Pb and As.

3. The wet etching method according to claim 1,
wherein the metal-containing film is a film made of a simple substance of the metal element, a film made of an alloy containing the metal element or a film made of a compound containing the metal element.

4. The wet etching method according to claim 1,
wherein the organic solvent is at least one kind of organic solvent selected from the group consisting of primary alcohols, secondary alcohols, tertiary alcohols, benzyl alcohols, ethers, esters, ketones, amines, amides, glycols, glycol ethers and halogenated alkanes.

5. The wet etching method according to claim 4,
wherein the organic solvent is at least one kind of organic solvent selected from the group consisting of isopropyl alcohol, methanol, ethanol, propylene glycol monomethyl ether acetate, methyl ethyl ketone and acetone.

6. The wet etching method according to claim 1,
wherein the amount of water contained in the etching solution is 1 mass % or less.

7. The wet etching method according to claim 1,
wherein the concentration of the β-diketone in the etching solution is 1 to 80 vol %.

8. The wet etching method according to claim 1,
wherein the β-diketone is at least one kind selected from the group consisting of hexafluoroacetylacetone, trifluoroacetylacetone, 1,1,1,6,6,6-hexafluoro-2,4-hexanedione, 4,4,4-trifluoro-1-(2-thienyl)-1,3-butanedione, 4,4,4-trifluoro-1-phenyl-1,3-butanedione, 1,1,1,5,5,5-hexafluoro-3-methyl-2,4-pentanedione, 1,1,1,3,5,5,5-heptafluoro-2,3-pentanedione and 1,1,1-trifluoro-5,5-dimethyl-2,4-hexanedione.

9. The wet etching method according to claim 1,
wherein the etching solution further contains a peroxide as an additive.

10. The wet etching method according to claim 9,
wherein the peroxide is at least one selected from the group consisting of hydrogen peroxide, peracetic acid, potassium percarbonate, ammonium persulfate, sodium persulfate, potassium persulfate and potassium peroxysulfate.

11. The wet etching method according to claim 1,
wherein the substrate is made of a silicon semiconductor material or a silicate glass material.

12. An etching solution comprising:
at least one kind of organic solvent selected from the group consisting of isopropyl alcohol, methanol, ethanol, propylene glycol monomethyl ether acetate, methyl ethyl ketone and acetone; and
a β-diketone having a trifluoromethyl group and a carbonyl group bonded to each other.

13. The etching solution according to claim 12
wherein the β-diketone is at least one kind selected from the group consisting of hexafluoroacetylacetone, trifluoroacetylacetone, 1,1,1,6,6,6-hexafluoro-2,4-hexanedione, 4,4,4-trifluoro-1-(2-thienyl)-1,3-butanedione, 4,4,4-trifluoro-1-phenyl-1,3-butanedione, 1,1,1,5,5,5-hexafluoro-3-methyl-2,4-pentanedione, 1,1,1,3,5,5,5-heptafluoro-2,3-pentanedione and 1,1,1-trifluoro-5,5-dimethyl-2,4-hexanedione.

14. The etching solution according to claim 12,
wherein the concentration of the β-diketone in the etching solution is 1 to 80 vol %.

15. The etching solution according to claim 12,
wherein the etching solution consists essentially of the organic solvent and the β-diketone.

16. The etching solution according to claim 12, further comprising a peroxide as an additive,
wherein the etching solution consists essentially of the organic solvent, the β-diketone and the additive.

17. A method for manufacturing a device, comprising etching a metal-containing film on a substrate by the wet etching method according to claim 1.
